(19) United States
(12) Patent Application Publication
(10) Pub. No.: US 2024/0332210 A1
(43) Pub. Date: Oct. 3, 2024

(54) OPTICAL PACKAGE WITH ELECTROMAGNETIC SHIELDING

(71) Applicant: STMicroelectronics International N.V., Geneva (CH)

(72) Inventors: Patrick LAURENT, Tullins (FR); Jean-Michel RIVIERE, Froges (FR)

(73) Assignee: STMicroelectronics International N.V., Geneva (CH)

(21) Appl. No.: 18/618,447

(22) Filed: Mar. 27, 2024

(30) Foreign Application Priority Data
Mar. 30, 2023 (FR) 2303109

(51) Int. Cl. H01L 23/552; H01L 31/02; H01L 31/0203; H01L 31/16

(52) U.S. Cl. CPC H01L 23/552; H01L 31/02016; H01L 31/0203; H01L 31/16

(57) ABSTRACT

An integrated circuit optical package includes a support substrate having a mounting face and an electrical interconnection network between the mounting face and contact pads located on a lower face of the support substrate. A cap includes a lateral wall fastened on the mounting face and an upper wall including a first opening. A first optical element is fastened on the upper wall of the cap to seal the first opening. An electromagnetic shielding element is embedded in the cap and configured to be coupled to a reference supply point via the interconnection network and at least one contact pad. A first electronic chip is mounted on the mounting face and in optical cooperation with the first optical element.

### PRIORITY CLAIM

This application claims the priority benefit of French Application for Patent No. 2303109, filed on Mar. 30, 2023, the content of which is hereby incorporated by reference in its entirety to the maximum extent allowable by law.

### TECHNICAL FIELD

Embodiments and implementations relate to the field of packaging integrated circuits and, in particular, the optoelectronics field, and more particularly the reduction of electromagnetic interferences within an integrated circuit optical package or in its vicinity.

### BACKGROUND

An integrated circuit optical package typically includes electronic chips capable of emitting or receiving an optical radiation (such as a laser, for example). A typical electronic chip of this kind of packages emits parasitic electromagnetic waves, in addition to the optical radiation, capable of propagating outside the optical package. These parasitic electromagnetic waves cause electromagnetic interference which might degrade and limit the performance of electronic systems in which the optical package is used. Indeed, the electromagnetic interference may occur in the vicinity of the optical package and disturb the operation of the circuits located around this package, in particular the circuits located on the same printed circuit board as that of the optical package.

Conversely, the optical package may be exposed to external parasitic electromagnetic waves, for example waves emitted by some of these circuits, at the origin of electromagnetic interference that might affect the performances of the package.

A conventional solution to this interference problem suggests the use of adhesive tapes designed to reduce, and possibly suppress, the electromagnetic interferences. The adhesive tape, bonded on a wall of the cap of the optical cap, prevents the propagation of the electromagnetic waves through this wall. In addition, the electromagnetic waves emitted by the chip of the package outwards of the package and the electromagnetic waves generated by circuits outside the package are blocked by the adhesive tape.

Nonetheless, an adhesive tape, often thick enough to block the electromagnetic waves, should be fixed on each wall of the cap to ensure an effective shielding of the package, and this contributes to increasing the size of the package. Hence, this solution may turn out to be complicated to set up in electronic systems for which the management of the space between the components becomes more and more important.

There is accordingly a need to find a solution allowing reducing, and even suppressing the electromagnetic interferences inside and around the package while making it compact, allowing for example facilitating the integration of the package in an electronic system.

### SUMMARY

According to one aspect, an integrated circuit optical package is provided including: a support substrate comprising a mounting face and an electrical interconnection network between the mounting face and contact pads located on a lower face of the support substrate, opposite to the mounting face; a cap having a lateral wall fastened on the mounting face and an upper wall including a first opening, the cap defining with the support substrate at least one first cavity; and a first optical element fastened on the upper wall of the cap and sealing the first opening.

According to this aspect, the package also includes: an electromagnetic shielding element embedded in the cap and intended to be coupled to a reference supply point, for example the ground, via the interconnection network and at least one contact pad; and a first electronic chip, for example a chip capable of emitting an optical radiation, mounted on the mounting face in said at least one first cavity and in optical cooperation with the first optical element.

The electromagnetic shielding element, typically made of an electrically-conductive material such as copper, forms a Faraday cage around the electronic chip and allows blocking the electromagnetic waves, for example the waves that might be emitted by the circuits in the vicinity of the package or those emitted by the electronic chip of the package.

In addition, the electromagnetic waves emitted by the electronic chip of the package are blocked by the shielding element and therefore cannot create interferences with the circuits in the vicinity of the optical package. The electronic chip is also protected by the electromagnetic shielding element from electromagnetic interferences.

Moreover, integrating the shielding element into the cap of the package allows making the package more compact.

Furthermore, the optical package, for example of the Land Grid Array (LGA) type provides for contact pads or lands connected to the interconnection network of the substrate and allowing electrically connecting the electronic chip to a printed circuit board. Thus, it is advantageously possible to use some of these contact pads to electrically connect the electromagnetic shielding element to a reference supply point, for example a ground, and thus achieve the electromagnetic shielding function of the package.

According to one embodiment, the electromagnetic shielding element is embedded in a molding resin.

The molding resin allows protecting the electromagnetic shielding element from deterioration, for example due to mechanical impacts or corrosion.

According to one embodiment, the shielding element also forms at least one inductive element.

Advantageously, the shielding element has another function, namely as an inductive element able to be connected to the electronic chip of the package.

According to one embodiment, the cap includes an additional wall extending in the first cavity, connected to the lateral wall and having an additional opening.

The package also includes an additional optical element fastened on the additional wall, sealing the additional opening and in optical cooperation with the first optical element and the first electronic chip.

Advantageously, the additional optical element also includes a circuit electrically connected to at least one other contact pad via an electrically-conductive connection embedded in the lateral wall of the cap and of the interconnection network.

The additional optical element allows ensuring an optical function (for example polarization, filtering, lens effect) while allowing preventing a failure, such as a delamination or a break-up of the additional optical element. Indeed, the circuit of the additional optical element allows detecting a failure of the optical element. More particularly, the circuit of the optical element allows forming with the electrically-conductive connection and the interconnection network a closed circuit in which a current continuously flows in the absence of failure and is interrupted when the circuit is open, for example upon break-up of the optical element.

Hence, the circuit of the optical element could be useful to control a cut-off of the power supply of the electronic chip so as to prevent it from emitting an optical radiation in the event of failure of the additional optical element for example.

According to one embodiment, the cap defines with the support substrate a second cavity, the upper wall of the cap includes a second opening leading into the second cavity, and the package comprises a second electronic chip, for example a chip, for example a chip capable of receiving an optical radiation, mounted on the mounting face of the support substrate in the second cavity.

The cap comprises a second optical element fastened on the upper wall of the cap, sealing the second opening and in optical cooperation with the second electronic chip, the electromagnetic shielding element, embedded in the cap surrounds the two electronic chips. The electromagnetic shielding element also allows protecting the second electronic chip from the electromagnetic interferences related to the electromagnetic waves originating from outside the optical package.

According to another aspect, a method is provided for manufacturing integrated circuit optical package comprising: providing a support substrate comprising a mounting face and a lower face opposite to the mounting face, the support substrate including contact pads located on the lower face and an electrical interconnection network between the mounting face and the contact pads; forming a cap having a lateral wall and an upper wall and including an electromagnetic shielding element embedded in the cap as well as a first opening; fastening a first optical element on the upper wall of the cap, the first optical element sealing the first opening; mounting a first electronic chip on the mounting face; and fastening the lateral wall of the cap on the mounting face of the substrate, the cap defining with the support substrate at least one first cavity, the first chip being located in said at least one first cavity and being in optical cooperation with the first optical element after said fastening of the lateral wall on the mounting face.

According to one implementation, the electromagnetic shielding element is embedded in a molding resin.

According to one implementation, the electromagnetic shielding element also forms at least one inductive element.

According to one implementation, forming the cap comprises embedding an electrically-conductive connection in the lateral wall, forming an additional wall connected to the lateral wall and extending in the first cavity when the lateral wall is fastened on the mounting face, and forming an additional opening in the additional wall, the method further comprising: fastening an additional optical element on the additional wall, the additional optical element including a circuit and sealing the additional opening, the optical element being in optical cooperation with the first optical element and the first electronic chip after said fastening of the lateral wall on the mounting face; and connecting said circuit of the additional optical element to at least one contact pad via the electrically-conductive connection and the interconnection network.

According to one implementation, embedding the electrically-conductive connection and embedding the electromagnetic shielding element are carried out simultaneously.

According to one implementation, forming the cap comprises forming a second opening in the upper wall, the cap defining with the support substrate a second cavity and the second opening leading into the second cavity when the lateral wall is fastened on the mounting face, the method further comprising: fastening a second optical element on the upper wall, the second optical element sealing the second opening; and mounting a second electronic chip on the mounting face, the second chip being located in said at least one second cavity and being in optical cooperation with the second optical element, then the electromagnetic shielding element surrounding the two electronic chips after said fastening of the lateral wall on the mounting face.

According to another aspect, a method is provided for connecting a package obtained by the method as defined before on a printed circuit board, comprising connecting said at least one contact pad electrically coupled to the shielding element on electrically-conductive connection of the printed circuit board intended to be connected to a reference supply point.

### BRIEF DESCRIPTION OF THE DRAWINGS

Other advantages and features of the invention will appear upon examining the detailed description of non-limiting embodiments and implementations, and from the appended drawings, wherein:

FIG. 1 schematically illustrates a sectional view of an integrated circuit optical package;

FIG. 2 illustrates a sectional view of the optical package with reference to FIG. 1;

FIG. 3 illustrates a sectional view of the cap with reference to FIG. 1;

FIG. 4 illustrates a sectional view of the cap with reference to FIG. 1; and

FIGS. 5 to 9 illustrate the steps of a method for manufacturing the optical package with reference to FIGS. 1 to 4.

### DETAILED DESCRIPTION

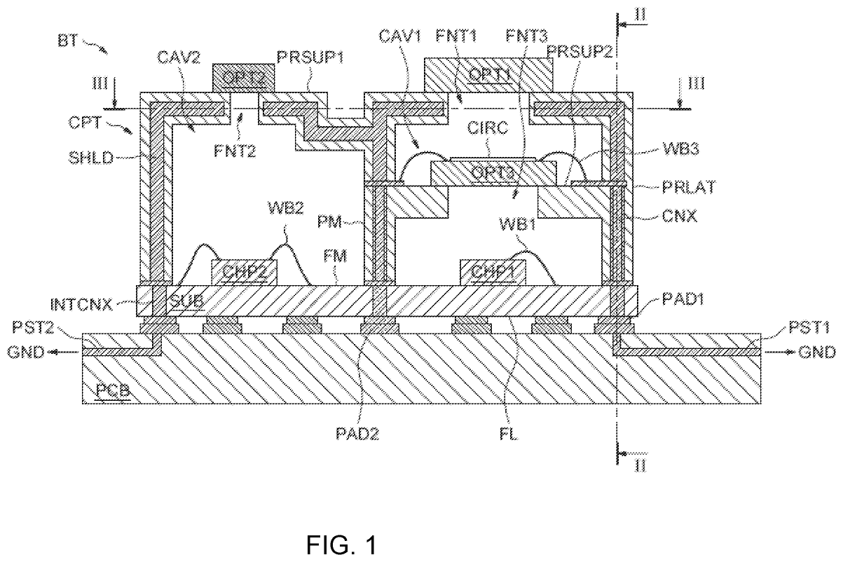

FIG. 1 schematically illustrates a sectional view of an integrated circuit optical package BT according to an embodiment.

The package BT includes a support substrate SUB comprising a mounting face FM and a lower face FL opposite to the mounting face FM. The substrate SUB comprises an electrical interconnection network INTCNX between the mounting face FM and contact pads PAD1, PAD2 located on the lower face FL. In the case of an LGA-type optical package, the contact pads PAD1 and PAD2 form a land grid array, typically made of copper, fixed and electrically connected to a printed circuit board PCB by welding for example. The printed circuit board PCB comprises electrically-conductive lines such as conductive tracks PST1, PST2, typically made of copper (Cu), integrated into one or several layers of dielectric material such as resin mixed with fiberglass and intended to be connected to a reference supply point, for example to ground GND.

The support substrate SUB has a structure that is conventional and known per se. The substrate SUB includes an interconnection network INTCNX also comprising conductive tracks, typically made of copper, integrated into one or more layer(s) of dielectric material such as resin mixed with fiberglass.

Consequently, the support substrate SUB is, in this case, a stratified support substrate (also referred to as a “laminate substrate”).

The optical package BT also comprises a first electronic integrated circuit (IC) chip CHP1, typically an emitter chip capable of emitting an infrared or laser type optical radiation for example, and a second electronic IC chip CHP2, typically a receiver chip capable of capturing an optical radiation.

The chips CHP1 and CHP2 are mounted and connected on the support substrate in a manner that is conventional and known per se, for example by means of welding wires (“wire bonding”) WB1 and WB2.

The optical package BT further includes a cap CPT having a lateral wall PRLAT fastened on the mounting face FM and an upper wall PRSUP1. The cap CPT defines with the support substrate SUB a first cavity CAV1 in which the first chip CHP1 is mounted, and a second cavity CAV2 in which the second chip CHP2 is mounted. In particular, the first cavity CAV1 and the second cavity CAV2 may be separated by a middle portion PM of the lateral wall of the cap CPT fastened on the mounting face FM.

Alternatively (not represented), this middle portion PM of the wall PRLAT could be not fastened to the mounting face FM and have an opening allowing mounting the second chip CHP2 which may then extend up to the first cavity CAV1. Hence, the foot of the middle wall PM of the lateral wall PRLAT may be positioned on a face of the second chip CHP2 or be spaced apart from the latter so that the first cavity CAV1 and the second cavity CAV2 communicate with each other.

Moreover, the upper wall PRSUP1 of the cap CPT comprises a first opening FNT1 and a second opening FNT2. The package BT further comprises a first optical element OPTI and a second optical element OPT2 fastened on the upper wall PRSUP1.

The first optical element OPTI seals the first opening FNT1 and is in optical cooperation with the first chip CHP1. The second optical element OPT2 seals the second opening FNT2 and is in optical cooperation with the second chip CHP2. For example, the first optical element OPT1 and the second optical element OPT2 are filters or lenses.

In operation, in addition to an optical radiation, the electronic chip CHP1 emits undesirable electromagnetic waves capable of propagating in several directions outwards of the package BT. These undesirable electromagnetic waves typically generate electromagnetic interference with electronic circuits that might be located in the vicinity of the package BT, for example circuits of the printed circuit board PCB, and if these waves are not blocked, might degrade or limit the performance of the electronic system in which the optical package is used.

Moreover, the first chip CHP1 and the second chip CHP2 may be sensitive to external electromagnetic waves, originating from the circuits located outside the package BT, which might degrade or limit their performance.

In this respect, the optical package BT includes an electromagnetic shielding element SHLD embedded in the cap CPT and capable of blocking the electromagnetic waves generated by the electronic chip CHP1 as well as those generated by the circuits outside the package BT. The electromagnetic shielding element SHLD is typically an electrical conductor, for example made of copper, and surrounds the two chips CHP1 and CHP2 thereby forming a Faraday cage. Furthermore, the shielding element SHLD is embedded in a molding resin allowing protecting it from deterioration, for example due to mechanical impacts or corrosion. The shielding element SHLD may be embedded in the middle portion PM of the lateral wall PRLAT separating the cavities CAV1 and CAV2 in order to prevent electromagnetic interference between the two chips CHP1 and CHP2 for example.

The electromagnetic shielding element SHLD is intended to be coupled to the reference supply point GND via the interconnection network INTCNX of the substrate SUB and one or more contact pad(s) PAD1. The contact pads PAD1 may be connected to the conductive tracks PST1, PST2 of the printed circuit board PCB by welding to enable coupling of the shielding element SHLD to the reference supply point GND and thus allow achieving shielding of the package BT.

The effectiveness of the shielding depends on parameters such as the used material, its thickness and the frequency to be blocked. A person skilled in the art should be able to adapt these parameters depending on the considered application so as to obtain a shielding element SHLD capable of blocking the electromagnetic waves generated by the first chip CHP1 as well as those originating from outside the package BT.

Thus, the shielding element SHLD allows avoiding interference with the circuits in the vicinity of the optical package BT and protecting the electronic chips CHP1 and CHP2 from interference that might be generated by the electromagnetic waves originating from outside the package BT. Furthermore, the shielding element SHLD contributes to making the package BT more compact since it is integrated into the cap CPT unlike an adhesive tape conventionally used as an electromagnetic shield which could increase the size of the package.

Advantageously, the cap CPT includes an additional wall PRSUP2 extending in the first cavity CAV1 and connected to the lateral wall PRLAT of the cap CPT. The additional wall PRSUP2 has an additional opening FNT3 which is, for example, aligned with the first opening FNT1 of the upper wall PRSUP1.

The package BT includes an additional optical element OPT3, for example a filter or a lens, including a circuit CIRC, and fastened on the additional wall PRSUP2. The additional optical element OPT3 is in optical cooperation with the first optical element OPT1 and the first electronic chip CHP1. In this manner, the first electronic chip CHP1 may receive an optical radiation passing through the first optical element OPTI and the additional optical element OPT3.

Of course, the circuit CIRC is positioned so as not hinder the pathway of the optical radiation. For example, it may be placed over the circumference of the lens or of the filter.

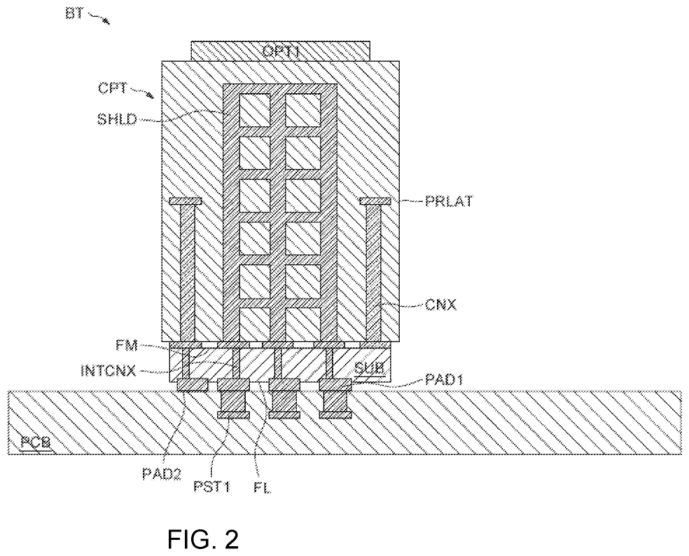

FIG. 2 illustrates a sectional view of the optical package BT described before with reference to FIG. 1 according to the section line II-II.

The circuit CIRC of the additional optical element OPT3 is electrically connected to at least one other contact pad PAD2, different from the contact pad PAD1, via an electrically-conductive connection CNX and the interconnection network INTCNX of the substrate SUB. In particular, the contact pad PAD2 is connected by welding to a conductive track (not represented) of the printed circuit board PCB. The electrically-conductive connection CNX is embedded in the lateral wall PRLAT of the cap CPT and is electrically separated from the shielding element SHLD by the molding resin.

For example, the circuit CIRC comprises conductive tracks which may be connected to the electrically-conductive connection CNX by electrically-conductive wires WB3. The electrically-conductive connection CNX is then electrically coupled to the contact pad PAD2 through the interconnection network INTCNX of the substrate SUB.

Consequently, the circuit CIRC forms with the electrically-conductive connection CNX and the interconnection network INTCNX a closed circuit in which a current could circulate, for example a current originating from the conductive track (not represented) of the printed circuit board PCB coupled to the connection pad PAD2. Such a circuit allows detecting a failure of the additional optical element OPT3 such as a delamination, for example in case of break-up of a conductive track of the circuit CIRC caused by the delamination. For example, the power supply of the first electronic chip CHP1 may be cut off when no current no longer circulate in the circuit CIRC of the optical element OPT3, so as to prevent the chip CHP1 from generating the optical radiation when a failure of the additional optical element OPT3 is detected.

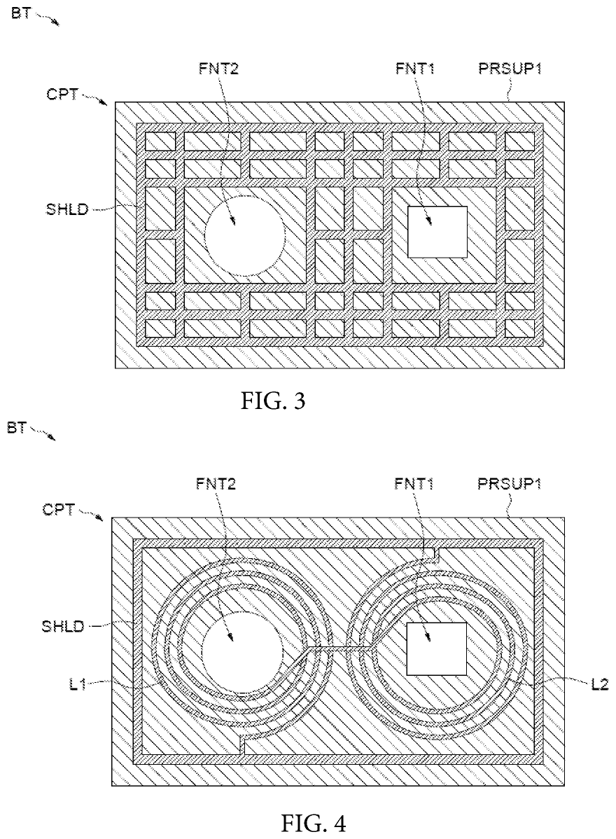

FIG. 3 illustrates a sectional view of the cap CPT described before with reference to FIG. 1 according to the section line III-III.

The electromagnetic shielding element SHLD may have several different shapes depending on the application and may, for example, form a grid allowing reducing the amount of material used for the manufacture of the shielding element SHLD while enabling the latter to ensure its electromagnetic wave blocking function.

FIG. 4 illustrates a sectional view of the cap CPT described before with reference to FIG. 1 according to the section line III-III according to a second embodiment.

Advantageously, the electromagnetic shielding element SHLD herein forms at least one inductive element, for example a first inductive element L1 and a second inductive element L2 enabling the circuits of the electronic chips CHP1 and CHP2 to be connected to these inductive elements.

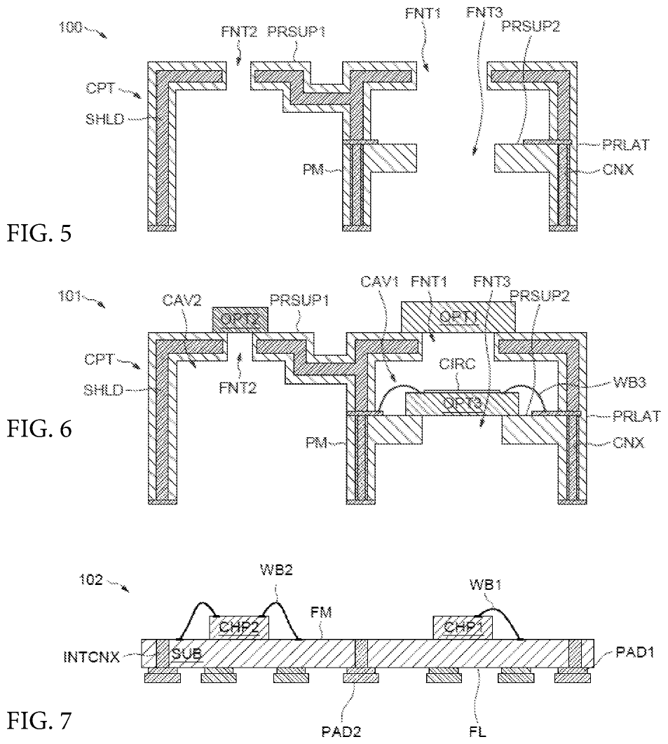

FIGS. 5 to 9 illustrate the steps of a method for manufacturing the optical package BT described before with reference to FIGS. 1 to 4 according to one implementation.

FIG. 5 schematically illustrates the result of a step 100 of forming the cap CPT.

The cap CPT has a lateral wall PRLAT and an upper wall PRSUP1. The cap CPT includes an electromagnetic shielding element SHLD embedded in the cap CPT as well as a first opening FNT1. Forming 100 the cap CPT also comprises forming a second opening FNT2 in the upper wall PRSUP1.

The shielding element SHLD is typically made of an electrically-conductive material such as copper and may have a different shape depending on the considered application. A person skilled in the art should be able to adapt the parameters of the shielding element SHLD such as the used material or its thickness so as to obtain a shielding element SHLD, capable of blocking the electromagnetic waves, for example those that might be generated by an electronic chip or by other circuits.

During this step 100, it is possible to form a cap CPT whose shielding element SHLD forms a grid like that one described with reference to FIG. 3 or advantageously forms at least one inductive element like the shielding element described with reference to FIG. 4.

In this step 100, the shielding element SHLD is embedded in a molding resin. Step 100 of forming the cap CPT also comprises embedding the electrically-conductive connection CNX in the lateral wall PRLAT and forming an additional wall PRSUP2 connected to the lateral wall PRLAT. In particular, embedding the electrically-conductive connection CNX is advantageously carried out at the same time as embedding the shielding element SHLD. Furthermore, step 100 comprises forming an additional opening FNT3 in the additional wall PRSUP2.

FIG. 6 schematically illustrates the result of a step 101 of fastening optical elements on the walls of the cap CPT.

In particular, step 101 comprises fastening, for example by gluing, a first optical element OPT1 and a second optical element OPT2 on the upper wall PRSUP1. The first optical element OPT1 seals the first opening FNT1 and the second optical element OPT2 seals the second opening FNT2. Furthermore, step 101 comprises fastening an additional optical element OPT3 including a circuit CIRC on the additional wall PRSUP2 and connecting the circuit CIRC to the electrically-conductive connection CNX, for example by conductive wires WB3. The additional optical element OPT3 seals the additional opening FNT3.

FIG. 7 schematically illustrates the result of a step 102 of providing a support substrate SUB and of mounting a first IC chip CHP1 and a second IC chip CHP2.

The support substrate SUB comprises a mounting face FM ad a lower face FL opposite to the mounting face FM. The support substrate SUB includes contact pads PAD1, PAD2 located on the lower face FL and an electrical interconnection network INTCNX between the mounting face FM and the contact pads PAD1, PAD2.

More particularly, step 102 comprises mounting a first chip CHP1, typically a chip capable of emitting an optical radiation, on the mounting face FM via conductive wires WB1, and mounting a second chip CHP2, typically a chip capable of receiving the optical radiation, on the mounting face FM via conductive wires WB2.

Step 102 may be carried out in parallel with steps 100 and 101 described before with reference to FIGS. 5 and 6, or before or after step 100 and/step 101 for example.

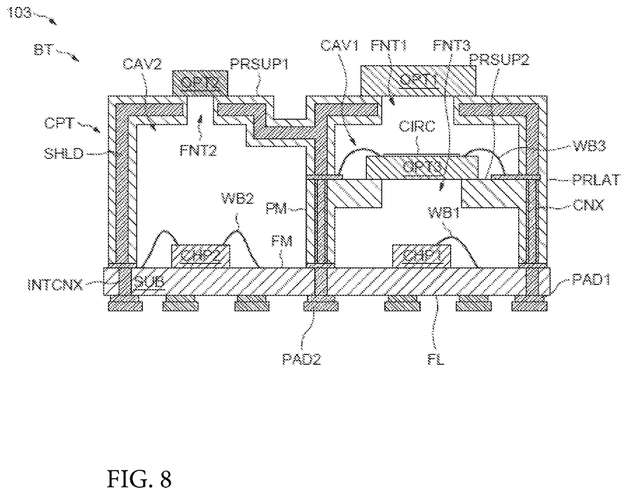

FIG. 8 schematically illustrates the result of a step 103 of fastening the lateral wall PRLAT of the cap CPT on the mounting face FM of the substrate SUB.

More particularly, the lateral wall PRLAT may be fastened on the mounting face FM, using a glue for example, so that the shielding element SHLD is coupled with the interconnection network INTCN of the substrate SUB.

When fastening the lateral wall PRLAT, the cap CPT defines with the support substrate SUB a first cavity CAV1 and a second cavity CAV2, the additional wall PRSUP2 extends in the first cavity CAV1, and the second opening FNT2 opens into the second cavity CAV2. The first chip CHP1 is located in the first cavity CAV1 and is in optical cooperation with the first optical element OPT1 and the additional optical element OPT3. Similarly, the second chip CHP2 is located in the second cavity CAV2 and is in optical cooperation with the second optical element OPT2.

The method further comprises connecting the circuit CIRC of the additional optical element OPT3 to one or more contact pad(s) PAD2, different from the contact pads PAD1 via the electrically-conductive connection CNX and the interconnection network INTCNX of the substrate SUB.

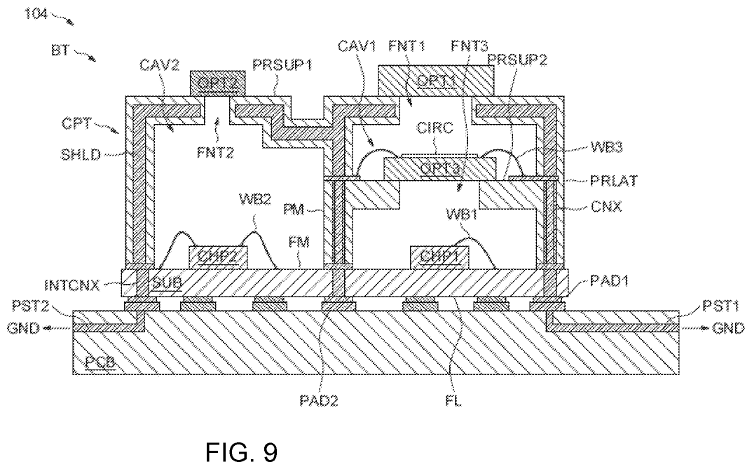

FIG. 9 schematically illustrates a method for connecting a package BT obtained by the method described before with reference to FIGS. 5 to 8, on a printed circuit board PCB.

In particular, the connection method comprises connecting the contact pads PAD1 electrically coupled to the shielding element SHLD on electrically-conductive tracks PST1, PST2 of the printed circuit board PCB. The electrically-conductive tracks PST1 and PST2 are connected to the reference supply point, for example a ground GND. Consequently, the electromagnetic shielding element SHLD may be connected to this ground GND via the contact pads PAD1, the interconnection network INTCNX and the tracks PST1, PST2,

Thus, the shielding element SHLD forms a Faraday cage around the electronic chips CHP1 and CHP2 capable of blocking the undesirable electromagnetic waves generated by the electronic chip CHP1 as well as those generated by the circuits outside the package BT.

1. An integrated circuit optical package, comprising:
a support substrate comprising a mounting face and an electrical interconnection network between the mounting face and contact pads located on a lower face of the support substrate, opposite to the mounting face;
a cap having a lateral wall fastened on the mounting face and an upper wall including a first opening, the cap defining with the support substrate at least one first cavity;
a first optical element fastened on the upper wall of the cap and sealing the first opening;
an electromagnetic shielding element embedded in the cap and configured to be coupled to a reference supply point via the interconnection network and at least one contact pad; and
a first electronic chip mounted on the mounting face in said at least one first cavity and in optical cooperation with the first optical element.

2. The package according to claim 1, wherein the electromagnetic shielding element is embedded in a molding resin forming the cap.

3. The package according to claim 2, wherein the shielding element forms at least one inductive element.

4. The package according to claim 1, wherein the cap includes an additional wall extending in the first cavity, said additional wall being connected to the lateral wall and having an additional opening, and further comprising an additional optical element fastened on the additional wall, sealing the additional opening and in optical cooperation with the first optical element and the first electronic chip, wherein the additional optical element includes a circuit electrically connected to at least one other contact pad via an electrically-conductive connection embedded in the lateral wall of the cap, wherein said at least one other contact pad is coupled to said interconnection network.

5. The package according to claim 1, wherein the circuit included with the additional optical element forms a sensor configured to detect a failure of the additional optical element, and wherein power to said first electronic chip is cut off in response to detection by the sensor of the failure of the additional optical element.

6. The package according to claim 5, wherein circuit comprises a conductive track, and wherein the failure of the additional optical element comprises a delamination which causes a break up of the conductive track.

7. The package according to claim 1, wherein the cap defines with the support substrate a second cavity, wherein the upper wall of the cap includes a second opening leading into the second cavity, and further comprising a second electronic chip mounted on the mounting face of the support substrate in the second cavity, and wherein the cap comprises a second optical element fastened on the upper wall of the cap, sealing the second opening and in optical cooperation with the second electronic chip, and wherein the electromagnetic shielding element is embedded in the cap surrounding the first and second electronic chips.

8. An integrated circuit optical package, comprising:
a support substrate comprising a mounting face and an electrical interconnection network between the mounting face and contact pads located on a lower face of the support substrate, opposite to the mounting face;
a cap having a lateral wall fastened on the mounting face, an upper wall including a first opening, wherein the cap defines with the support substrate a first cavity, an additional wall extending in the first cavity, said additional wall being connected to the lateral wall and having an additional opening;
a first optical element fastened on the upper wall of the cap and sealing the first opening;
an additional optical element fastened on the additional wall and sealing the additional opening;
a first electronic chip mounted on the mounting face in said first cavity;
wherein the first electronic chip is in optical cooperation with both the first optical element and said additional optical element.

9. The package according to claim 8, wherein the additional optical element includes a circuit comprising a sensor configured to detect a failure of the additional optical element.

10. The package according to claim 9, wherein said circuit is electrically connected to a contact pad via an electrically-conductive connection embedded in the lateral wall of the cap, wherein said contact pad is coupled to said interconnection network.

11. The package according to claim 9, wherein the circuit is configured, in response to detection by the sensor of the failure of the additional optical element, cut off power to said first electronic chip.

12. The package according to claim 9, further comprising an electromagnetic shielding element embedded in the cap and electrically coupled to the interconnection network.

13. The package according to claim 12, wherein the shielding element forms at least one inductive element.

14. The package according to claim 9, wherein the cap defines with the support substrate a second cavity, wherein the upper wall of the cap includes a second opening leading into the second cavity, and further comprising a second electronic chip mounted on the mounting face of the support substrate in the second cavity, and wherein the cap comprises a second optical element fastened on the upper wall of the cap and sealing the second opening and in optical cooperation with the second electronic chip.

15. A method for manufacturing an integrated circuit optical package, comprising:
providing a support substrate comprising a mounting face and a lower face opposite to the mounting face, the support substrate including contact pads located on the lower face and an electrical interconnection network between the mounting face and the contact pads;
forming a cap having a lateral wall and an upper wall and including an electromagnetic shielding element embedded in the cap as well as a first opening;
fastening a first optical element on the upper wall of the cap, the first optical element sealing the first opening;
mounting a first electronic chip on the mounting face; and
fastening the lateral wall of the cap on the mounting face of the substrate, the cap defining with the support substrate at least one first cavity, the first electronic chip being located in said at least one first cavity and being in optical cooperation with the first optical element after said fastening of the lateral wall on the mounting face.

16. The method according to claim 15, wherein forming the cap comprises embedding the electromagnetic shielding element in a molding resin.

17. The method according to claim 16, wherein forming the cap further comprises forming the electromagnetic shielding element as at least one inductive element.

18. The method according to claim 15, wherein forming the cap comprises:
embedding an electrically-conductive connection in the lateral wall;
forming an additional wall connected to the lateral wall and extending in the first cavity when the lateral wall is fastened on the mounting face, and forming an additional opening in the additional wall;
the method further comprising:
fastening an additional optical element on the additional wall, the additional optical element including a circuit and sealing the additional opening, the optical element being in optical cooperation with the first optical element and the first electronic chip after said fastening of the lateral wall on the mounting face; and
connecting said circuit of the additional optical element to at least one contact pad via the electrically-conductive connection and the interconnection network.

19. The method according to claim 18, wherein embedding the electrically-conductive connection and embedding the electromagnetic shielding element are carried out simultaneously.

20. The method according to claim 15, wherein forming the cap comprises forming a second opening in the upper wall, the cap defining with the support substrate a second cavity and the second opening leading into the second cavity when the lateral wall is fastened on the mounting face;
the method further comprising:
fastening a second optical element on the upper wall, the second optical element sealing the second opening; and
mounting a second electronic chip on the mounting face, the second electronic chip being located in said at least one second cavity and being in optical cooperation with the second optical element, then the electromagnetic shielding element surrounding the first and second electronic chips after said fastening of the lateral wall on the mounting face.

21. A method, comprising:
manufacturing the integrated circuit optical package according to claim 15; and
connecting said at least one contact pad electrically coupled to the shielding element on an electrically-conductive track of the printed circuit board which is configured to be connected to a reference supply point.
